(19) United States
(12) Patent Application Publication
(10) Pub. No.: US 2023/0044486 A1
(43) Pub. Date: Feb. 9, 2023

(54) LIQUID COOLING JACKET AND COOLING DEVICE

(71) Applicant: Nidec Corporation, Kyoto (JP)

(72) Inventors: Masaaki HANANO, Kyoto (JP); Koji MURAKAMI, Kyoto (JP)

(21) Appl. No.: 17/879,038

(22) Filed: Aug. 2, 2022

(30) Foreign Application Priority Data
Aug. 5, 2021 (JP) 2021-129112

(51) Int. Cl. F28D 15/00; F28F 1/40

(52) U.S. Cl. CPC F28D 15/00; F28F 1/40

(57) ABSTRACT

A liquid cooling jacket includes a refrigerant flow path which is a flow path having a width in a second direction and in which a heat dissipation assembly is located on a first side in a third direction, where a direction in which a refrigerant flows is defined as a first direction. The refrigerant flow path includes a narrow flow path portion. A width in the third direction of the narrow flow path portion is smaller than a width in the third direction of a flow path on a first side in the first direction with respect to the narrow flow path portion and a width in the third direction of a flow path on a second side in the first direction with respect to the narrow flow path portion.

### CROSS-REFERENCE TO RELATED APPLICATIONS

The present application claims priority under 35 U.S.C. § 119 to Japanese Patent Application No. 2021-129112, filed on Aug. 5, 2021, the entire contents of which are hereby incorporated herein by reference.

### FIELD OF THE INVENTION

The present disclosure relates to a liquid cooling jacket.

### BACKGROUND

Conventionally, a water jacket used for water cooling is known. A heat dissipation member is accommodated in the water jacket. The inside of the water jacket serves as a flow path of cooling water, and a heating element is water-cooled via the heat dissipation member.

Here, further improvement in cooling performance by a water jacket has been recently desired.

### SUMMARY

A liquid cooling jacket according to an example embodiment of the present disclosure includes a refrigerant flow path which is a flow path having a width in a second direction and in which a heat dissipation assembly can be provided on a first side in a third direction, where a direction in which a refrigerant flows is defined as a first direction, a direction orthogonal to the first direction is defined as the second direction, and a direction orthogonal to the first direction and the second direction is defined as the third direction. The refrigerant flow path includes a narrow flow path portion. A width in the third direction of the narrow flow path portion is smaller than a width in the third direction of a flow path on a first side in the first direction with respect to the narrow flow path portion and a width in the third direction of a flow path on a second side in the first direction with respect to the narrow flow path portion, where a downstream side is defined as the first side in the first direction, and an upstream side is defined as the second side in the first direction.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is an exploded perspective view of a cooling device according to a first example embodiment of the present disclosure.

FIG. 2 is a plan view and a cross-sectional view taken along line I-I of the cooling device according to the first example embodiment.

FIG. 3 is a partially enlarged view of the cross section taken along line I-I illustrated in FIG. 2.

FIG. 4 is a cross-sectional view taken along line II-II of the cooling device according to the first example embodiment.

FIG. 5 is a cross-sectional view taken along line II-II of the cooling device according to a first variation of an example embodiment of the present disclosure.

FIG. 6 is a cross-sectional view taken along line II-II of the cooling device according to a second variation of an example embodiment of the present disclosure.

FIG. 7 is a cross-sectional view taken along line II-II of the cooling device according to a third variation of an example embodiment of the present disclosure.

FIG. 8 is a cross-sectional view taken along line II-II of the cooling device according to a fourth variation of an example embodiment of the present disclosure.

FIG. 9 is a cross-sectional view taken along line I-I of the cooling device according to a fifth variation of an example embodiment of the present disclosure.

FIG. 10 is a cross-sectional view taken along line I-I of the cooling device according to a sixth variation of an example embodiment of the present disclosure.

FIG. 11 is a cross-sectional view taken along line I-I of the cooling device according to a seventh variation of an example embodiment of the present disclosure.

FIG. 12 is a partially enlarged view of a cross-sectional view taken along line I-I of the cooling device according to an eighth variation of an example embodiment of the present disclosure.

FIG. 13 is a plan view and a cross-sectional view taken along line I-I of the cooling device according to a second example embodiment of an example embodiment of the present disclosure.

FIG. 14 is a partial plan view of the cooling device according to a third example embodiment of an example embodiment of the present disclosure.

FIG. 15 is a partial plan view of the cooling device according to a fourth example embodiment of an example embodiment of the present disclosure.

FIG. 16 is a partial plan view and a partial side sectional view of the cooling device according to a fifth example embodiment of an example embodiment of the present disclosure.

### DETAILED DESCRIPTION

Hereinafter, example embodiments of the present disclosure will be described with reference to the drawings.

In the drawings, with the first direction as an X direction, X1 indicates a first side in the first direction, and X2 indicates a second side in the first direction. The first direction is a direction along a direction F in which a refrigerant W flows, and the downstream side is indicated by F1 and the upstream side is indicated by F2. The downstream side F1 is the first side in the first direction, and the upstream side F2 is the second side in the first direction. With the second direction orthogonal to the first direction as a Y direction, Y1 indicates a first side in the second direction, and Y2 indicates a second side in the second direction. With the third direction orthogonal to the first direction and the second direction as a Z direction, Z1 indicates a first side in the third direction, and Z2 indicates a second side in the third direction. Note that the above-described “orthogonal” also includes intersection at an angle slightly shifted from 90 degrees. Each of the above-described directions does not limit a direction when a cooling device 1 is incorporated in various devices.

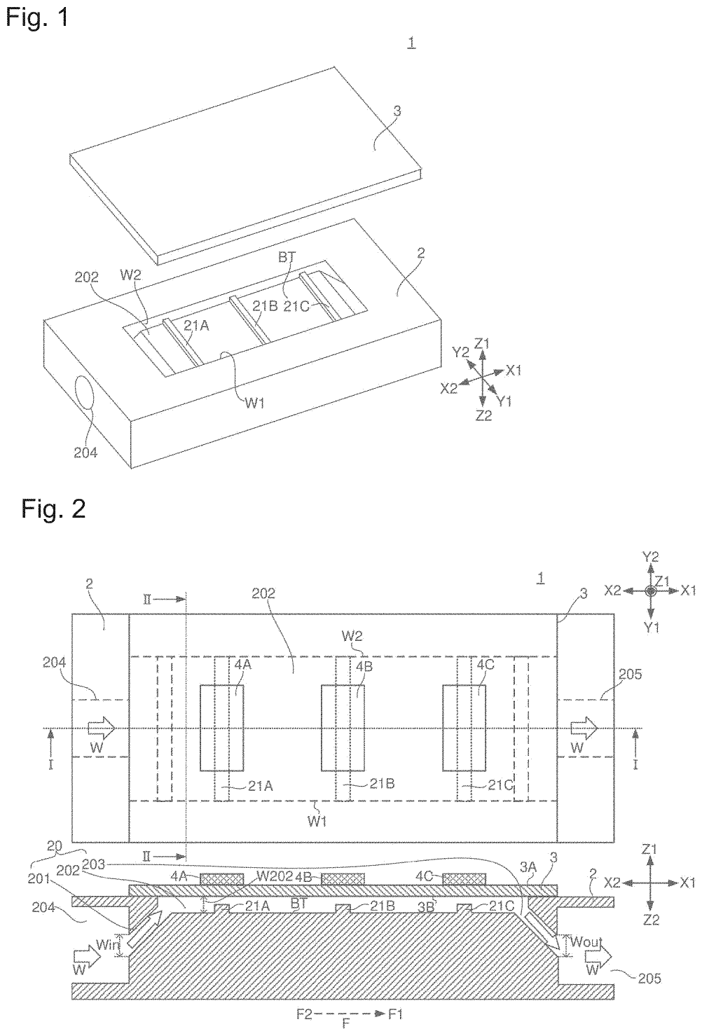

FIG. 1 is an exploded perspective view of the cooling device 1 according to a first example embodiment. FIG. 2 is a plan view (upper diagram) and a side sectional view taken along line I-I (lower diagram) of the cooling device 1 according to the first example embodiment as viewed from the first side in the third direction. As illustrated in FIG. 2, the line I-I is a center line passing through the center position in the second direction in the plan view of the cooling device 1.

The cooling device 1 includes a liquid cooling jacket 2 and a heat dissipation assembly 3. The cooling device 1 is a device that cools a plurality of heating elements 4A, 4B, and 4C with the refrigerant W. The refrigerant W is liquid such as water. That is, the cooling device 1 performs liquid cooling such as water cooling. The number of heating elements may be a plural number other than three, or may be singular.

The liquid cooling jacket 2 has a rectangular parallelepiped shape having sides extending in the first direction, the second direction, and the third direction. The liquid cooling jacket 2 is, for example, a die-cast product made from metal such as aluminum. The liquid cooling jacket 2 has a flow path for allowing the refrigerant W to flow in the inside.

Specifically, the liquid cooling jacket 2 includes a refrigerant flow path 20, an inlet flow path 204, and an outlet flow path 205. The inlet flow path 204 is arranged in an end portion on the second side in the first direction of the liquid cooling jacket 2 and has a columnar shape extending in the first direction.

The refrigerant flow path 20 includes a first flow path 201, a second flow path 202, and a third flow path 203. The first flow path 201 has a width in the second direction and is inclined to the first side in the first direction and the first side in the third direction. An end portion on the second side in the first direction of the first flow path 201 is connected to an end portion on the first side in the first direction of the inlet flow path 204. The second flow path 202 has a width in the second direction and extends in the first direction. An end portion on the second side in the first direction of the second flow path 202 is connected to an end portion on the first side in the first direction of the first flow path 201. The third flow path 203 has a width in the second direction and is inclined to the first side in the first direction and the second side in the third direction. An end portion on the first side in the first direction of the second flow path 202 is connected to an end portion on the second side in the first direction of the third flow path 203.

The outlet flow path 205 is arranged in an end portion on the first side in the first direction of the liquid cooling jacket 2 and has a columnar shape extending in the first direction. An end portion on the first side in the first direction of the third flow path 203 is connected to an end portion on the second side in the first direction of the outlet flow path 205.

In this manner, the refrigerant W flowing into the inlet flow path 204 flows into the first flow path 201 and flows to the first side in the first direction and the first side in the third direction in the first flow path 201, flows into the second flow path 202 and flows to the first side in the first direction in the second flow path 202, flows into the third flow path 203 and flows to the first side in the first direction and the second side in the third direction in the third flow path 203, and flows into the outlet flow path 205 and is discharged to the outside of the liquid cooling jacket 2.

Here, the heat dissipation assembly 3 is a rectangular parallelepiped flat plate having sides extending in the first direction, the second direction, and the third direction, and has thickness in the third direction. The heat dissipation assembly 3 is, for example, a copper plate. In a state where the heat dissipation assembly 3 is not attached to the liquid cooling jacket 2, the first side in the third direction of each of the first flow path 201, the second flow path 202, and the third flow path 203 is exposed to the outside. The heat dissipation assembly 3 is attached to the liquid cooling jacket 2 by being arranged on the first side in the third direction of the first flow path 201, the second flow path 202, and the third flow path 203. In this manner, the first side in the third direction of each of the first flow path 201, the second flow path 202, and the third flow path 203 is not exposed to the outside.

That is, the liquid cooling jacket 2 is a flow path having a width in the second direction, and has the refrigerant flow path 20 in which the heat dissipation assembly 3 can be arranged on the first side in the third direction.

The heating elements 4A, 4B, and 4C are arranged side by side in this order on the first side in the first direction. The heating elements 4A, 4B, and 4C are in direct or indirect contact with a side surface 3A on the first side in the third direction of the heat dissipation assembly 3. Heat generated from the heating elements 4A, 4B, and 4C is transmitted to the refrigerant W flowing through the second flow path 202 via the heat dissipation assembly 3, so that the heating elements 4A, 4B, and 4C are cooled.

The liquid cooling jacket 2 includes a plurality of flow path defining portions 21A, 21B, and 21C. The number of the flow path defining portions is three in accordance with the number of the heating elements 4A, 4B, and 4C (hereinafter, 4A and the like). Note that the number of the flow path defining portions may be a plural number other than three, or may be singular.

A wall portion W1 extending in the first direction and the third direction is provided on the first side in the second direction of the second flow path 202. A wall portion W2 expanding in the first direction and the third direction is provided on the second side in the second direction of the second flow path 202.

The flow path defining portions 21A and the like protrude to the first side in the third direction from a bottom surface portion BT arranged on the second side in the third direction of the second flow path 202. The flow path defining portions 21A and the like have a columnar shape extending in the second direction and are arranged from the wall portion W1 to the wall portion W2. The flow path defining portions 21A and the like have a quadrangular prism shape having a quadrangular cross section as viewed in the second direction.

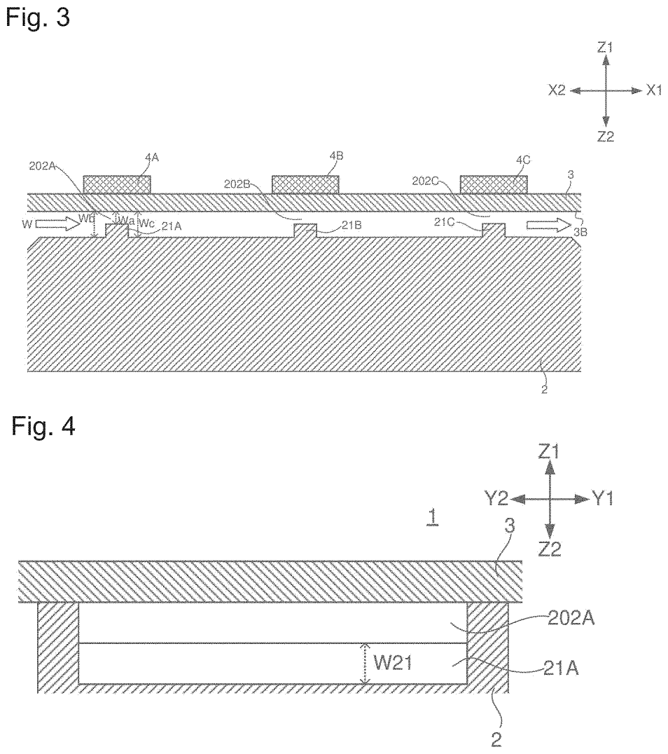

Here, FIG. 3 is a partially enlarged view of a side sectional view illustrated in FIG. 2. As illustrated in FIG. 3, narrow flow path portions 202A, 202B, and 202C (hereinafter, 202A and the like) are arranged between a surface on the first side in the third direction of the flow path defining portions 21A and the like and a surface 3B on the second side in the third direction of the heat dissipation assembly 3. The flow path defining portions 21A and the like are arranged on the second side in the third direction of the narrow flow path portions 202A and the like. An optional width in the third direction of the narrow flow path portion 202A is smaller than a third direction width We of the flow path on the first side in the first direction with respect to the narrow flow path portion 202A, and is smaller than a third direction width Wb of the flow path on the second side in the first direction with respect to the narrow flow path portion 202A. The same applies to the narrow flow path portions 202B and 202C.

That is, the refrigerant flow path 20 includes the narrow flow path portions 202A and the like. The width in the third direction of the narrow flow path portions 202A and the like is smaller than the width in the third direction of the flow path on the first side in the first direction with respect to the narrow flow path portion 202A and the width in the third direction of the flow path on the second side in the first direction with respect to the narrow flow path portion 202A. By increasing the flow velocity of the refrigerant W by the narrow flow path portions 202A and the like, turbulent flow is likely to occur, and cooling performance for cooling the heating elements 4A and the like can be improved.

As described above, the liquid cooling jacket 2 has the bottom surface portion BT arranged on the second side in the third direction of the refrigerant flow path 20. The flow path defining portions 21A and the like protrude from the bottom surface portion BT to the first side in the third direction. In this manner, the flow path defining portions 21A and the like can be easily formed.

The flow path defining portions 21A and the like are arranged from an end on the first side in the second direction to an end on the second side in the second direction of the refrigerant flow path 20. In this manner, the flow velocity of the refrigerant W can be increased in the entire range of the refrigerant flow path 20 in the second direction.

When viewed in the third direction, a part of each of the flow path defining portions 21A and the like overlaps each of the heating elements 4A and the like. That is, at least a part of the narrow flow path portions 202A and the like overlaps the heating elements 4A and the like when viewed in the third direction. In this manner, the flow velocity of the refrigerant W can be increased at a position where the heating elements 4A and the like are arranged, and the cooling performance for cooling the heating elements 4A and the like can be improved.

As illustrated in FIG. 2, a third direction width Win of an end portion on the second side in the first direction of the first flow path 201 is larger than the width in the third direction of the narrow flow path portions 202A and the like. A third direction width Wout of an end portion on the first side in the first direction of the third flow path 203 is larger than the width in the third direction of the narrow flow path portion 202A and the like. That is, the third direction width Wout of an end portion on the first side in the first direction of the refrigerant flow path 20 and the third direction width Win of an end portion on the second side in the first direction of the refrigerant flow path 20 are larger than the width in the third direction of the narrow flow path portions 202A and the like. In this manner, the width in the third direction can be widened at an inlet and an outlet of the refrigerant flow path 20, and pressure loss can be reduced.

As illustrated in FIG. 2, the width Win in the third direction of an end portion on the second side in the first direction of the first flow path 201 is larger than a width W202 in the third direction of the second flow path 202, and the width Wout in the third direction of an end portion on the first side in the first direction of the third flow path 203 is larger than the width W202 in the third direction of the second flow path 202. That is, the third direction width Wout of an end portion on the first side in the first direction of the refrigerant flow path 20 and the third direction width Win of an end portion on the second side in the first direction of the refrigerant flow path 20 are larger than the third direction width W202 of a portion other than the narrow flow path portions 202A and the like in the flow path 202 including the narrow flow path portions 202A and the like. By increasing the widths of the inlet and the outlet of the refrigerant flow path 20 in the third direction, pressure loss at the inlet and the outlet can be reduced.

The cooling device 1 according to the present example embodiment includes the liquid cooling jacket 2 and the heat dissipation assembly 3 having a flat plate shape that is arranged on the first side in the third direction of the refrigerant flow path 20, spreads in the first direction and the second direction, and has thickness in the third direction. In this manner, it is possible to improve the cooling performance by the narrow flow path portions 202A and the like while reducing the cost without providing a fin such as a pin fin in the heat dissipation assembly.

FIG. 4 is a cross-sectional view taken along line II-II of the cooling device 1 according to the first example embodiment described above. The line II-II extends in the second direction at a position on the second side in the first direction of the flow path defining portion 21A in the plan view of FIG. 2.

In the flow path defining portion 21A illustrated in FIG. 4, a width W21 in the third direction is constant in the second direction. However, as described in various variations below, the width W21 in the third direction of the flow path defining portion 21A may change along the second direction.

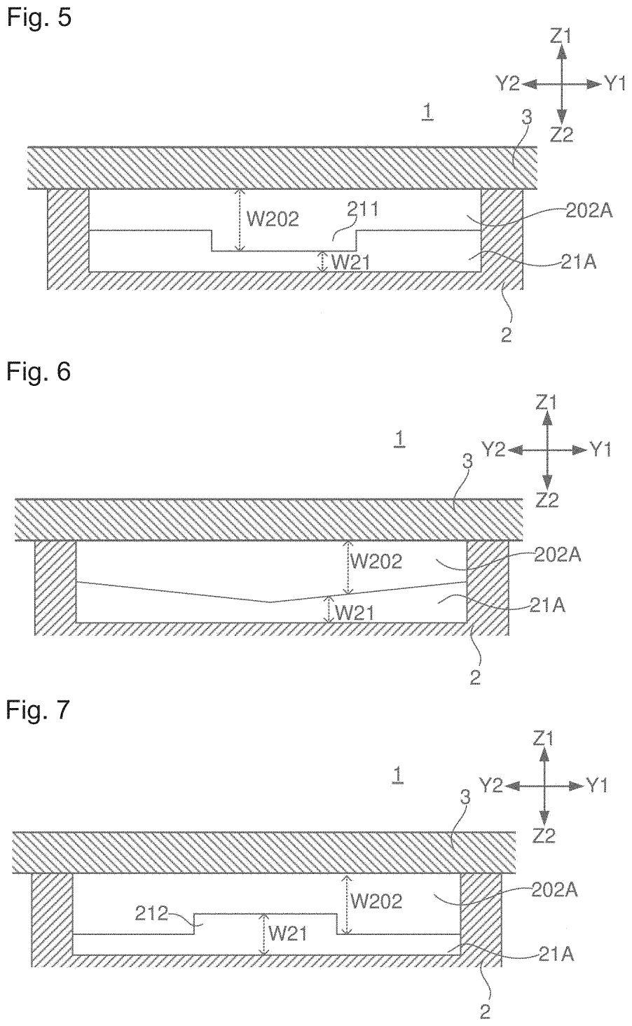

FIG. 5 is a cross-sectional view taken along line II-II of the cooling device 1 according to a first variation. The flow path defining portion 21A illustrated in FIG. 5 has a recessed flow path 211 recessed to the second side in the third direction in a center portion in the second direction. That is, the width W21 in the third direction of the flow path defining portion 21A is smaller at the location of the recessed flow path 211 than at locations other than the location. In this manner, the width W202 in the third direction of the narrow flow path portion 202A is larger at the location of the recessed flow path 211 than at locations other than the location. Therefore, pressure loss can be adjusted.

FIG. 6 is a cross-sectional view taken along line II-II of the cooling device 1 according to a second variation. The width W21 in the third direction of the flow path defining portion 21A illustrated in FIG. 6 gradually decreases from both ends in the second direction of the second flow path 202 toward the center in the second direction. In this manner, the width W202 in the third direction of the narrow flow path portion 202A gradually increases from both ends of the second flow path 202 in the second direction toward the center in the second direction. Even in such an example embodiment, pressure loss can be adjusted.

FIG. 7 is a cross-sectional view taken along line II-II of the cooling device 1 according to a third variation. The flow path defining portion 21A illustrated in FIG. 7 has a protruding portion 212 protruding to the first side in the third direction at a center portion in the second direction. That is, the width W21 in the third direction of the flow path defining portion 21A is larger at the location of the protruding portion 212 than at locations other than the location. In this manner, the width W202 in the third direction of the narrow flow path portion 202A becomes smaller at the location of the protruding portion 212 than at locations other than the location. Therefore, the flow velocity of the refrigerant W can be increased at the location of the protruding portion 212 in the narrow flow path portion 202A, that is, at the location where the heating element 4A is arranged, which is advantageous for cooling the heating element 4A.

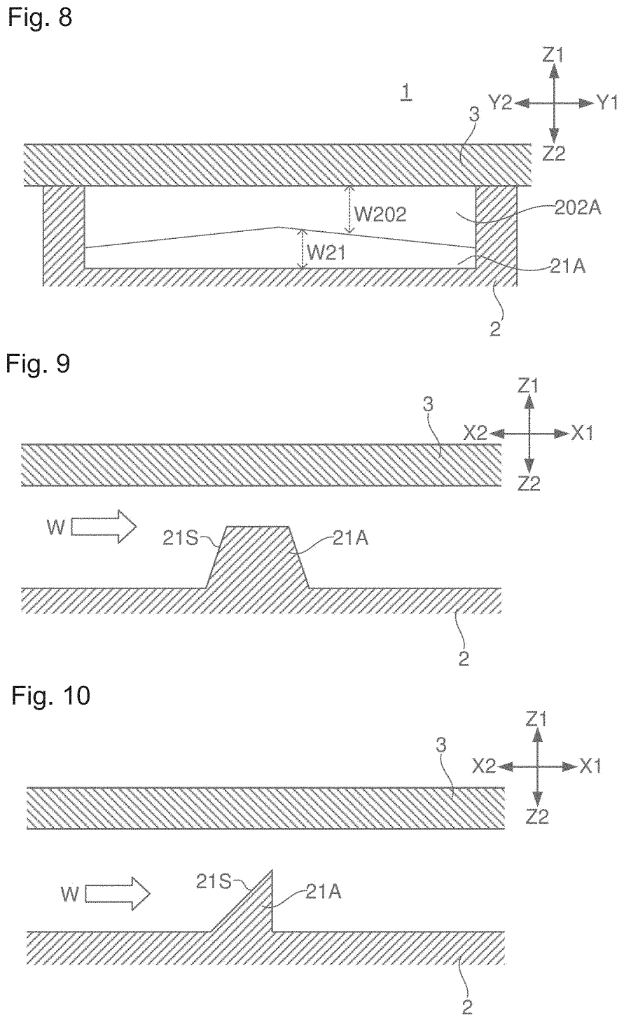

FIG. 8 is a cross-sectional view taken along line II-II of the cooling device 1 according to a fourth variation. The width W21 in the third direction of the flow path defining portion 21A illustrated in FIG. 8 gradually increases from both ends in the second direction of the second flow path 202 toward the center in the second direction. In this manner, the width W202 in the third direction of the narrow flow path portion 202A gradually decreases from both ends of the second flow path 202 in the second direction toward the center in the second direction. Therefore, the flow velocity of the refrigerant W can be increased at the location at the center in the second direction in the narrow flow path portion 202A, that is, at the location where the heating element 4A is arranged, which is advantageous for cooling the heating element 4A.

In the first example embodiment described above, the flow path defining portions 21A and the like have a quadrangular prism shape having a quadrangular cross section as viewed in the second direction, but the present disclosure is not limited to this.

FIGS. 9 to 11 are partially enlarged views taken along line I-I of the cooling device 1 according to fifth to seventh variations. The flow path defining portion 21A illustrated in FIG. 9 has a columnar shape having a trapezoidal cross section when viewed in the second direction. In this manner, an inclined surface 21S inclined to the first side in the first direction and the first side in the third direction can be provided on the second side in the first direction in the flow path defining portion 21A. As the refrigerant W flows along the inclined surface 21S, pressure loss can be reduced.

The flow path defining portion 21A illustrated in FIG. 10 has a columnar shape having a triangular cross section as viewed in the second direction. In this manner, an inclined surface 21S inclined to the first side in the first direction and the first side in the third direction can be provided on the second side in the first direction in the flow path defining portion 21A. As the refrigerant W flows along the inclined surface 21S, pressure loss can be reduced.

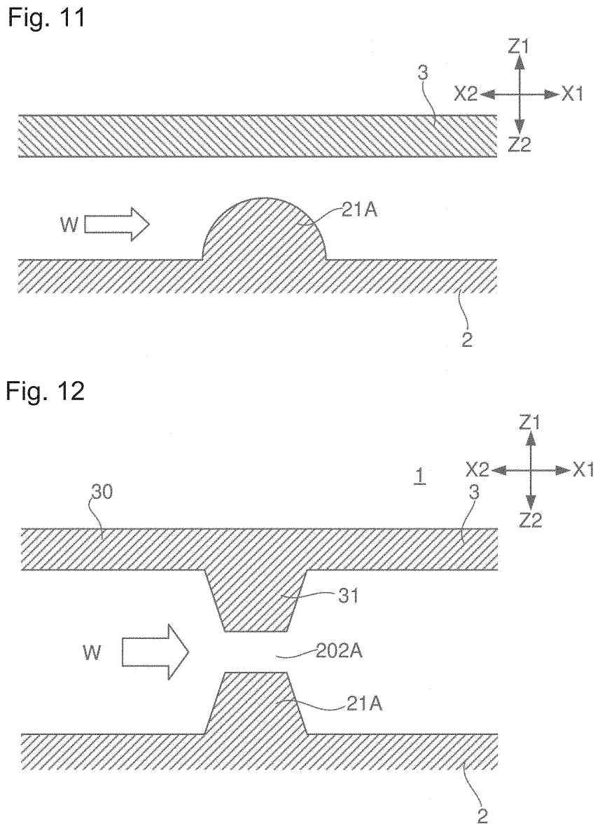

The flow path defining portion 21A illustrated in FIG. 11 has a columnar shape having a semicircular cross section when viewed in the second direction. In this manner, a semicircular arc surface can be provided on a surface of the flow path defining portion 21A. As the refrigerant W flows along the arc surface, pressure loss can be reduced.

FIG. 12 is a partially enlarged view of a cross section taken along line I-I of the cooling device 1 according to an eighth variation. In the configuration illustrated in FIG. 12, the heat dissipation assembly 3 has a facing portion 31 that protrudes from a surface on the second side in the third direction of a flat plate portion 30 to the second side in the third direction thereof. The facing portion 31 faces the flow path defining portion 21A in the third direction. The narrow flow path portion 202A is arranged between the facing portion 31 and the flow path defining portion 21A. In FIG. 12, as an example, both the facing portion 31 and the flow path defining portion 21A have a trapezoidal columnar cross section as viewed in the second direction.

That is, the cooling device 1 includes the liquid cooling jacket 2 having the flow path defining portion 21A arranged on the second side in the third direction of the narrow flow path portion 202A, and the heat dissipation assembly 3 having the facing portion 31 arranged on the first side in the third direction of the refrigerant flow path 20 and facing the flow path defining portion 21A in the third direction. As the narrow flow path portion 202A is provided between the flow path defining portion 21A and the facing portion 31, the width in the third direction of the narrow flow path portion 202A can be further reduced, and the flow velocity of the refrigerant W can be further increased.

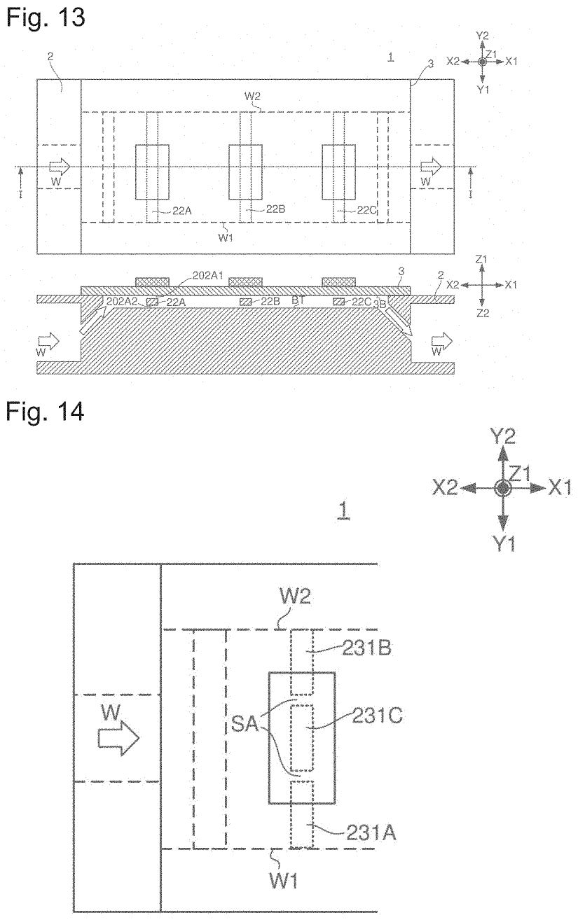

FIG. 13 is a plan view (upper diagram) and a side sectional view taken along line I-I (lower diagram) of the cooling device 1 according to the second example embodiment as viewed from the first side in the third direction. The liquid cooling jacket 2 according to the present example embodiment includes flow path defining portions 22A, 22B, and 22C (hereinafter, 22A and the like).

The flow path defining portions 22A and the like are arranged from the wall portions W1 to W2, and are arranged further on the first side in the third direction than the bottom surface portion BT and further on the second side in the third direction than the surface 3B on the second side in the third direction of the heat dissipation assembly 3. That is, the flow path defining portion 22A and the like are arranged closer to the second side in the third direction than the first side end in the third direction of the refrigerant flow path 20. The narrow flow path portion is formed by the flow path defining portions 22A and the like, and cooling performance for cooling the heating element can be improved.

Therefore, as illustrated in FIG. 13, a first narrow flow path portion 202A1 is arranged between the flow path defining portion 22A and the surface 3B on the second side in the third direction, and a second narrow flow path portion 202A2 is arranged between the flow path defining portion 22A and the bottom surface portion BT. That is, the liquid cooling jacket 2 includes the flow path defining portion 22A arranged on the second side in the third direction of the narrow flow path portion 202A1. Further, the liquid cooling jacket 2 includes the flow path defining portion 22A arranged on the first side in the third direction of the narrow flow path portion 202A2.

Note that a narrow flow path portion may be provided between the flow path defining portion protruding from the bottom surface portion BT as shown in the first example embodiment and the flow path defining portion 22A. In this case, the liquid cooling jacket 2 includes the flow path defining portions arranged on the first side in the third direction and the second side in the third direction of the narrow flow path portion.

That is, the liquid cooling jacket 2 may include a flow path defining portion arranged on at least one of the first side in the third direction and the second side in the third direction of the narrow flow path portion. The narrow flow path portion is formed by the flow path defining portion, and cooling performance for cooling the heating element can be improved.

FIG. 14 is a partial plan view of the cooling device 1 according to a third example embodiment as viewed in the third direction. The liquid cooling jacket 2 according to the present example embodiment includes flow path defining portions 231A, 231B, and 231C. The narrow flow path portion is arranged on the first side in the third direction of the flow path defining portions 231A, 231B, and 231C.

The flow path defining portion 231A protrudes from the wall portion W1 to the second side in the second direction. The flow path defining portion 231B protrudes from the wall portion W2 to the first side in the second direction. The flow path defining portion 231C is arranged between the flow path defining portion 231A and the flow path defining portion 231B. Spaces SA are provided between an end on the second side in the second direction of the flow path defining portion 231A and an end on the first side in the second direction of the flow path defining portion 231C, and between an end on the second side in the second direction of the flow path defining portion 231C and an end on the first side in the second direction of the flow path defining portion 231B.

That is, the flow path defining portions 231A, 231B, and 231C are adjacent to the space SA in the second direction. In the space SA, since the width in the second direction is narrow, the flow velocity of the refrigerant W is increased, and turbulent flow is likely to occur. Further, the cost can be suppressed as compared with a case where the flow path defining portion is provided in the entire second direction of the refrigerant flow path 20.

Note that, between the flow path defining portion 231A and the flow path defining portion 231B, a space may be provided without providing the flow path defining portion.

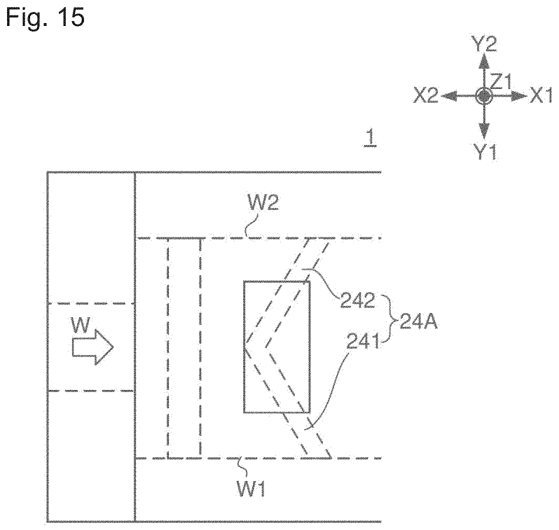

FIG. 15 is a partial plan view of the cooling device 1 according to a fourth example embodiment as viewed in the third direction. The liquid cooling jacket 2 according to the present example embodiment includes a flow path defining portion 24A.

The flow path defining portion 24A has a first column portion 241 and a second column portion 242. The first column portion 241 and the second column portion 242 protrude from the bottom surface portion BT toward the first side in the third direction. The first column portion 241 protrudes from the wall portion W1 toward the second side in the first direction and the second side in the second direction as viewed in the third direction. The second column portion 242 protrudes from the wall portion W2 to the second side in the first direction and the first side in the second direction as viewed in the third direction. An end on the second side in the second direction of the first column portion 241 and an end on the first side in the second direction of the second column portion 242 are connected. In this manner, the flow path defining portion 24A has a V-shape protruding toward the second side in the first direction as viewed in the third direction. A narrow flow path portion is provided on the first side in the third direction of the flow path defining portion 24A.

The flow path defining portion may have a V-shape protruding toward the first side in the first direction as viewed in the third direction.

That is, when viewed in the third direction, the flow path defining portion 24A is inclined to the first side in the first direction or the second side in the first direction with respect to the second direction. In this manner, since the refrigerant W flows along an inclined surface on the second side in the first direction in the flow path defining portion 24A, pressure loss can be reduced.

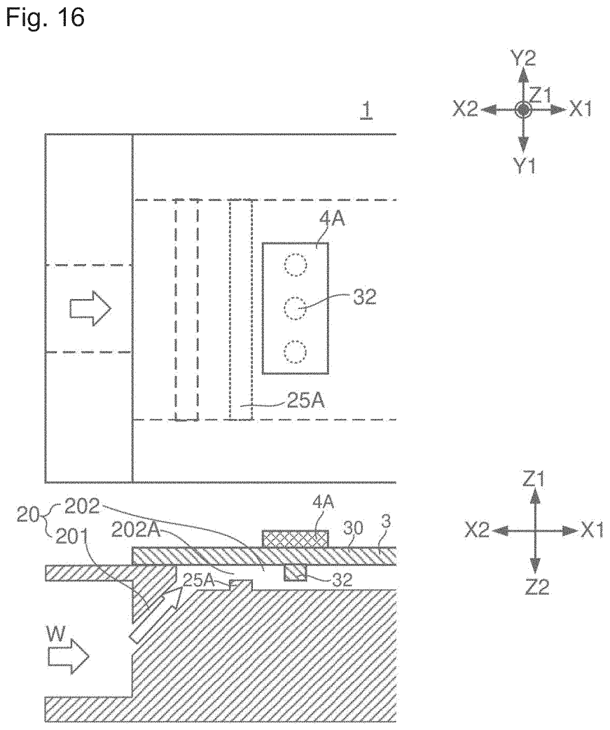

FIG. 16 is a partial plan view and a partial side sectional view of the cooling device 1 according to a fifth example embodiment as viewed in the third direction. The liquid cooling jacket 2 according to the present example embodiment includes a flow path defining portion 25A. A configuration of the flow path defining portion 25A is similar to that of the flow path defining portion 21A of the first example embodiment.

The flow path defining portion 25A is arranged on the second side in the first direction of the heating element 4A as viewed in the third direction. Therefore, the narrow flow path portion 202A provided on the first side in the third direction of the flow path defining portion 25A is arranged on the second side in the first direction of the heating element 4A as viewed in the third direction.

The heat dissipation assembly 3 includes the flat plate portion 30 and a pin fin 32. The pin fin 32 protrudes in a columnar shape from a surface on the second side in the third direction of the flat plate portion 30 to the second side in the third direction thereof. The pin fin 32 is accommodated in the second flow path 202. The pin fin 32 overlaps the heating element 4A as viewed in the third direction.

That is, the cooling device 1 includes the liquid cooling jacket 2 in which the narrow flow path portion 202A is arranged on the second side in the first direction of the heating element 4A and the heat dissipation assembly 3 arranged on the first side in the third direction of the refrigerant flow path 20 as viewed in the third direction. The heat dissipation assembly 3 includes the pin fin 32 that is arranged in the refrigerant flow path 20 at a position overlapping the heating element 4A as viewed in the third direction and extends in a columnar shape in the third direction. In this manner, the flow velocity of the refrigerant W can be increased by the narrow flow path portion 202A on the upstream side of the heating element 4A, turbulence is easily generated by the pin fin 32 located on the downstream side of the narrow flow path portion 202A, and the performance of cooling the heating element 4A by the pin fins 32 can be improved.

The example embodiment of the present disclosure is described above. Note that the scope of the present disclosure is not limited to the above example embodiment. The present disclosure can be implemented by making various changes to the above-described example embodiment without departing from the gist of the disclosure. The matters described in the above example embodiment can be optionally combined together, as appropriate, as long as there is no inconsistency.

For example, the heat dissipation assembly is not limited to a metal plate, and may be a vapor chamber or a heat pipe.

The present disclosure can be used for cooling various heating elements.

Features of the above-described preferred example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A liquid cooling jacket comprising:
a refrigerant flow path which is a flow path having a width in a second direction and in which a heat dissipation assembly is provided on a first side in a third direction, where a direction in which a refrigerant flows is defined as a first direction, a direction orthogonal to the first direction is defined as the second direction, and a direction orthogonal to the first direction and the second direction is defined as the third direction; wherein
the refrigerant flow path includes a narrow flow path portion; and
a width in the third direction of the narrow flow path portion is smaller than a width in the third direction of a flow path on a first side in the first direction with respect to the narrow flow path portion and a width in the third direction of a flow path on a second side in the first direction with respect to the narrow flow path portion, where a downstream side is defined as the first side in the first direction, and an upstream side is defined as the second side in the first direction.

2. The liquid cooling jacket according to claim 1, further comprising a flow path defining portion on at least one of the first side in the third direction and a second side in the third direction of the narrow flow path portion.

3. The liquid cooling jacket according to claim 2, further comprising:
a bottom surface portion on the second side in the third direction of the refrigerant flow path; wherein
the flow path defining portion protrudes from the bottom surface portion to the first side in the third direction.

4. The liquid cooling jacket according to claim 2, further comprising:
a bottom surface portion on the second side in the third direction of the refrigerant flow path; wherein
the flow path defining portion is located farther on a first side in the third direction than the bottom surface portion and farther on the second side in the third direction than an end on the first side in the third direction of the refrigerant flow path.

5. The liquid cooling jacket according to claim 2, wherein the flow path defining portion extends from an end on a first side in the second direction to an end on a second side in the second direction of the refrigerant flow path.

6. The liquid cooling jacket according to claim 2, wherein the flow path defining portion is adjacent to a space in the second direction.

7. The liquid cooling jacket according to claim 2, wherein the flow path defining portion is inclined to the first side in the first direction or the second side in the first direction with respect to the second direction as viewed in the third direction.

8. The liquid cooling jacket according to claim 2, wherein a width in the third direction of the flow path defining portion changes along the second direction.

9. The liquid cooling jacket according to claim 1, wherein at least a portion of the narrow flow path portion overlaps a heating element when viewed in the third direction.

10. The liquid cooling jacket according to claim 1, wherein a third direction width of an end portion on the first side in the first direction of the refrigerant flow path and a third direction width of an end portion on the second side in the first direction of the refrigerant flow path are larger than a width in the third direction of the narrow flow path portion.

11. The liquid cooling jacket according to claim 1, wherein a third direction width of an end portion on the first side in the first direction of the refrigerant flow path and a third direction width of an end portion on the second side in the first direction of the refrigerant flow path are larger than a third direction width of a portion other than the narrow flow path portion in a flow path including the narrow flow path portion.

12. A cooling device comprising:
the liquid cooling jacket according to claim 1, including a flow path defining portion on a second side in the third direction of the narrow flow path portion; and
a heat dissipation assembly on the first side in the third direction of the refrigerant flow path and includes an opposing portion opposing the flow path defining portion in the third direction.

13. A cooling device comprising:
the liquid cooling jacket according to claim 1; and
a heat dissipation assembly having a flat plate shape, the heat dissipation assembly being on the first side in the third direction of the refrigerant flow path, extending out in the first direction and the second direction, and having a thickness in the third direction.

14. A cooling device comprising:
the liquid cooling jacket according to claim 1, in which the narrow flow path portion is on the second side in the first direction of a heating element as viewed in the third direction; and
a heat dissipation assembly on the first side in the third direction of the refrigerant flow path; wherein
the heat dissipation assembly includes a pin fin in the refrigerant flow path at a position overlapping the heating element as viewed in the third direction and extending in a columnar shape in the third direction.
